(19) United States
(12) Patent Application Publication
(10) Pub. No.: US 2025/0201651 A1
(43) Pub. Date: Jun. 19, 2025

(54) SEMICONDUCTOR PACKAGE WITH DOUBLE-SIDED THERMAL SOLUTION AND METHOD FOR FORMING THE SAME

(71) Applicant: Taiwan Semiconductor Manufacturing Company, Ltd., Hsinchu (TW)

(72) Inventors: Shih-Wei Liu, Chiayi City (TW); Singda Jiang, Taichung City (TW); Tsunyen Wu, Hsinchu County (TW); Kathy Wei Yan, Hsinchu (TW)

(21) Appl. No.: 18/629,044

(22) Filed: Apr. 8, 2024

Related U.S. Application Data
(60) Provisional application No. 63/611,868, filed on Dec. 19, 2023.

(51) Int. Cl. H01L 23/367; H01L 23/00; H01L 23/31; H01L 23/373; H01L 23/473; H01L 25/065

(52) U.S. Cl. CPC H01L 23/3675; H01L 23/3107; H01L 23/3736; H01L 23/473; H01L 24/13; H01L 24/29; H01L 24/73; H01L 25/0652; H01L 2224/13005; H01L 2224/13025; H01L 2224/29021; H01L 2224/2919; H01L 2224/73153; H01L 2924/06; H01L 2924/1431; H01L 2924/1434; H01L 2924/182; H01L 2924/351

(57) ABSTRACT

A semiconductor package and the method for forming the same are provided. The semiconductor package includes a substrate having an upper surface and a lower surface, first integrated circuit devices mounted on the upper surface, and second integrated circuit devices mounted on the lower surface. A first heat spreader in the form of a vapor-chamber (VC) is located over the first integrated circuit devices. A second heat spreader in the form of a vapor-chamber is located over the second integrated circuit devices. A heat-transfer member thermally couples the first heat spreader and the second heat spreader on both sides of the substrate.

### PRIORITY CLAIM AND CROSS-REFERENCE

This application claims the benefit of U.S. Provisional Application No. 63/611,868, filed on Dec. 19, 2023, the entirety of which is incorporated by reference herein.

### BACKGROUND

The semiconductor integrated circuit (IC) industry has experienced exponential growth. Technological advances in IC materials and design have produced generations of ICs, where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. Such scaling down has also increased the complexity of processing and manufacturing ICs.

ICs are typically assembled into packages, which in turn are connected to a system board, such as a printed circuit board. During operation, the ICs generate heat which raises the temperature of the package. Without removal of the heat, there may be a thermal impact on the ICs performance or reliability, as well as the packaging materials performance or reliability. In some cases, a heat sink can be incorporated into the package to facilitate the removal of heat from the IC environment.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a vertical cross-sectional view of a semiconductor package with a double-sided heat dissipation module, in accordance with some embodiments.

FIG. 2 is a plan view (e.g., a top-down view) showing the arrangement of the first integrated circuit devices and the upper vapor-chamber (VC) heat spreader over the upper surface of the substrate in FIG. 1, in accordance with some embodiments, where the components below the upper VC heat spreader are represented by dotted lines.

FIG. 3 schematically shows the internal structure of the upper VC heat spreader in FIG. 1 and the working principle of the upper VC heat spreader during operation, in accordance with some embodiments.

FIG. 4 is a plan view (e.g., a bottom-up view) showing the arrangement of the second integrated circuit devices and the lower VC heat spreader over the lower surface of the substrate in FIG. 1, in accordance with some embodiments, where the components above the lower VC heat spreader are represented by dotted lines.

FIG. 5 schematically shows the internal structure of the lower VC heat spreader with upwardly extending VC heat-transfer channels in FIG. 1 and the working principle of the lower VC heat spreader during operation, in accordance with some embodiments.

FIGS. 6A to 6C illustrate vertical cross-sectional views of intermediate steps of forming the semiconductor package with the double-sided heat dissipation module in FIG. 1, in accordance with some embodiments.

FIG. 7 is a vertical cross-sectional view of a first alternative of a semiconductor package with a double-sided heat dissipation module, in accordance with some embodiments.

FIG. 8 is a vertical cross-sectional view of a second alternative of a semiconductor package with a double-sided heat dissipation module, in accordance with some embodiments.

FIG. 9 is a vertical cross-sectional view of a third alternative of a semiconductor package with a double-sided heat dissipation module, in accordance with some embodiments.

FIG. 10 is a vertical cross-sectional view of a fourth alternative of a semiconductor package with a double-sided heat dissipation module, in accordance with some embodiments.

FIG. 11 is a vertical cross-sectional view of a fifth alternative of a semiconductor package with a double-sided heat dissipation module, in accordance with some embodiments.

FIG. 12 is a vertical cross-sectional view of a sixth alternative of a semiconductor package with a double-sided heat dissipation module, in accordance with some embodiments.

FIG. 13 is a vertical cross-sectional view of a seventh alternative of a semiconductor package with a double-sided heat dissipation module, in accordance with some embodiments.

FIG. 14 is a plan view (e.g., a bottom-up view) showing the arrangement of the second integrated circuit devices and the lower VC heat spreader (and the heat-pipe (HP) heat-transfer channels attached thereto) over the lower surface of the substrate in FIG. 13, in accordance with some embodiments.

FIG. 15 is a flowchart of a method of using a double-sided heat dissipation module to dissipate heat from a semiconductor package.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, so that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The system may be otherwise oriented (rotated 90 degrees or at other orientations) and the spatially relative descriptors used herein may likewise be interpreted accordingly.

Three-dimensional integrated circuits (3D-ICs) packaging offers many solutions to reduce the physical size of packaged components and allows for a greater number of components to be placed in a given chip area. One solution offered by 3D-IC packaging is to stack dies on top of one another and interconnect or route them through interconnections such as through-silicon vias (TSVs). Some of the benefits of 3D-IC packaging include, for example, a smaller footprint, reduced power consumption by reducing the length of signal interconnects, and improved yield and fabrication cost if individual dies are tested separately prior to assembly.

High-performance computing (HPC) has become increasingly popular and widely used in advanced networking and server applications, especially for artificial intelligence (AI) related products that require high data rates, increased bandwidth and reduced latency. A commonly used 3D-IC packaging architecture in high-performance computing (HPC) applications is the chip-on-wafer-on-substrate (CoWoS) architecture, which typically consists of multiple chip-on-wafer (CoW) dies/devices mounted on a substrate (e.g., its upper surface). Recently, in order to improve space utilization, components other than the CoW dies (e.g., voltage regulator modules (VRMs), etc.), can be mounted on the lower surface of the substrate. However, this poses a challenge for heat dissipation of these components below the substrate as they are not directly attached to the heat sink located on top of the package, which causes thermal issues for these components and the entire package.

Embodiments described herein relate to a semiconductor package including a double-sided (also referred to sandwich-like) heat dissipation module for use in a system-on-substrate architecture, such as for a CoWoS architecture that includes multiple integrated circuit devices on both sides of the substrate, and methods of forming the same. In some embodiments, the double-sided heat dissipation module includes a first (or upper) vapor-chamber (VC) heat spreader and a second (or lower) VC heat spreader, which are thermally coupled to the integrated circuit devices mounted on upper and lower surfaces of the substrate, respectively, so that the heat generated by these integrated circuit devices can be quickly spread across the first and second VC heat spreaders to avoid the formation of localized hot spots. Also, the first and second VC heat spreaders located on opposite sides of the substrate are thermally connected using one or more heat-transfer channels/members to allow heat energy to be transferred from the lower VC heat spreader to the upper VC heat spreader. The upper VC heat spreader further dissipates the heat to the external environment, such as through air cooling. Accordingly, the heat generated by the integrated circuit devices mounted on both sides of the substrate can be effectively dissipated simultaneously through the double-sided heat dissipation module, which will be described in more detail below. This reduces thermal issues on those packaged components and the entire package, thereby improving product reliability.

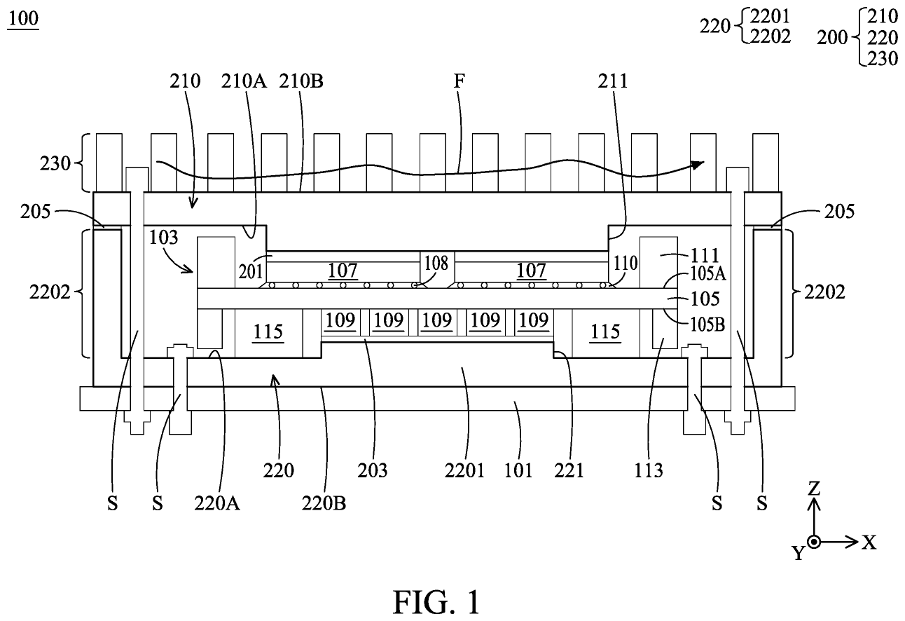

With reference now to FIG. 1, a vertical cross-sectional view of a semiconductor package 100 is shown in accordance with some embodiments. The semiconductor package 100 includes a system board 101 bonded to a first side (e.g., the lower side shown) of a 3D-IC package module 103. In some embodiments, the system board 101 is a print circuit board (PCB), which may be used to interconnect various electronic components within the package in order to provide the desired functionality for the user. Conductive features (e.g., conductive lines, vias, contact pads, etc.), electronic components (e.g., active or passive components), and/or I/O interface connectors (e.g., slots) on and/or within the system board 101 are not shown for the sake of simplicity. In some embodiments, the system board 101 may be coupled both electrically and physically to another substrate on a side of the system board 101 opposite the 3D-IC package module 103. Another substrate may provide a structural base and an electrical interface from the system board 101 and/or the 3D-IC package module 103 to other devices and systems. In some embodiments, the system board 101 may be bonded to another substrate using external connections (not shown), which may be solder balls or other suitable conductive connections.

The 3D-IC package module 103 may be a CoWoS architecture, which may include a substrate 105 (also referred to as an interposer), a plurality of first package components 107 mounted on the upper surface 105A of the substrate 105, and a plurality of second package components 109 mounted on the lower surface 105B of the substrate 105. In some embodiments, the first package components 107 and the second package components 109 may be different types of integrated circuit (IC) devices (which will be described below), but the disclosure is not limited thereto.

The substrate 105 is used to interconnect the first package components 107 and the second package components 109 on both sides of the substrate 105. In some embodiments, the substrate 105 may be a semiconductor substrate, which may be a bulk semiconductor substrate, a silicon-on-insulator (SOI) substrate, a multi-layered semiconductor substrate, or the like. The semiconductor material of the substrate 105 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 105 may be doped or undoped.

In some embodiments, the substrate 105 may include conductive pads, conductive routing, and through substrate vias (TSVs) (not shown). The conductive routing may provide electrical interconnections, and may electrically couple the conductive pads and the TSVs. The conductive routing may include one or more layers of conductive lines, conductive vias, redistribution layers, metallization patterns, or the like. In some embodiments, the substrate 105 may or may not include active and/or passive components (e.g., transistors, diodes, resistors, capacitors, and the like).

In some embodiments, the first package components 107 (also referred to herein as first IC devices) may include a plurality of high-performance semiconductor dies, which may be used for processing of 3D smart internet TV graphics or other processing intense applications, for example. In some embodiments, the first package components 107 may include processor (e.g., central processing unit (CPU), graphic processing unit (CPU), etc.) dies, memory (e.g., dynamic random access memory (DRAM), high bandwidth memory (HBM), memory stacks, etc.) dies, or other suitable semiconductor IC dies. The first package components 107 may all be the same type of package components having an identical structure, or may include a plurality of different types of package components. In addition, the first package components 107 may or may not have the same dimensions (e.g., height in the z-direction and/or area in the x-y plane).

In some embodiments, the first package components 107 each include a semiconductor substrate having a plurality of IC die components thereon to form a functional integrated circuit. The IC die components may comprise IC dies or stacks of IC dies. In some embodiments, the first package components 107 may be system-on-chip (SoC) devices, system-on-integrated-circuit (SoIC) devices, or the like. For simplicity, the detailed internal configuration of first package components 107 is not shown. The first package components 107 can be obtained, for example, by sawing or dicing a semiconductor wafer (with several IC dies or stacks of IC dies pre-formed thereon) along scribed lines to separate the semiconductor wafer into a plurality of individual semiconductor dies. In this manner, each of the first package components 107 can also be referred to as a chip-on-wafer (CoW) die/device.

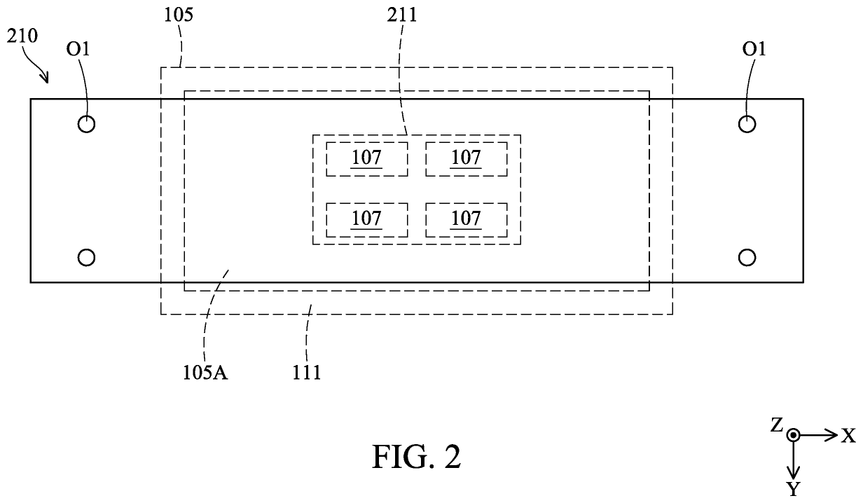

During assembly, the first package components 107 may be placed over the upper surface 105A of the substrate 105 using, for example, a pick-and-place tool. In an illustrative embodiment, four first package components 107 may be arranged in a rectangular matrix over the upper surface 105A of the substrate 105 as shown in FIG. 2, although other numbers and/or arrangements of the first package components 107 may also be used. The first package components 107 may be bonded to the upper surface 105A of the substrate 105 via a plurality of conductive connectors 108. In some embodiments, the conductive connectors 108 may be microbumps, although other suitable conductive connectors may also be used.

In some embodiments, an underfill material 110 is dispensed into the gaps between each of the first package components 107 and the substrate 105 to surround and protect the conductive connectors 108. The underfill material 110 may include an epoxy, a resin, a filler material, a stress release agent (SRA), an adhesion promoter, another suitable material, or a combination thereof. In some embodiments, the underfill material 110 is dispensed in a liquid state and then cured. In other embodiments, the underfill material 110 may be omitted.

In some embodiments, an encapsulant (not shown for simplicity) is encapsulated (sometimes referred to as molded) on the first package components 107. The encapsulant fills the gaps between neighboring first package components 107, and further covers the first package components 107. The encapsulant may include a molding compound, a molding underfill, or the like. The encapsulant may include a polymer material, such as an epoxy-based resin with fillers dispersed therein. In some embodiments, the encapsulant is dispensed in a liquid state and then cured. In a subsequent step, a planarization process (e.g., a chemical mechanical polishing (CMP) process or a mechanical grinding process) may be applied on the encapsulant to partially remove the encapsulant material, until the top surfaces of the first package components 107 are exposed from the encapsulant. This facilitates the dissipation of heat generated from the first package components 107.

In some embodiments, the second package components 109 (also referred to herein as second IC devices) may include a plurality of voltage regulator modules (VRMs). Each VRM may include one or more power components (not shown), and such components are used as part of a power conditioning circuit. In operation, the VRM receives a “pre-conditioned” direct current (DC) input from a power supply (not shown) and further conditions the input to remove transient voltages and the like. This power condition functionality is accomplished by passing the input voltage through various filer components, including passive and/or active filter elements. Other functionalities (e.g., power distribution, power converter, etc.) may also be provided by the VRMs. In other embodiments, the second package components 109 may include other types of integrated circuit devices that generate heat during operation, and are not limited to VRMs.

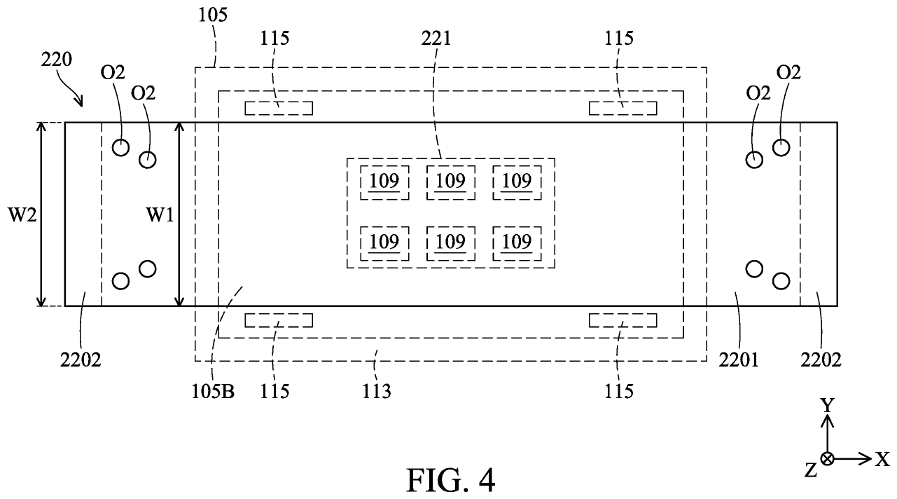

During assembly, the second package components 109 may be placed over the lower surface 105B of the substrate 105 using, for example, a pick-and-place tool. In an illustrative embodiment, six second package components 109 may be arranged in a rectangular matrix over the lower surface 105B of the substrate 105 as shown in FIG. 4, although other numbers and/or arrangements of the second package components 109 may also be used. The second package components 109 may be bonded to the lower surface 105B of the substrate 105 via a plurality of conductive connectors (not shown for simplicity). In some embodiments, the conductive connectors may be microbumps, although other suitable conductive connectors may also be used.

In some embodiments, underfill material and/or an encapsulant (not shown) may also be applied adjacent the second package components 109 to protect the second package components 109 and the respective conductive connectors, similar to the previously discussed underfill material 110 and/or encapsulant applied adjacent the first package components 107.

As mentioned above, by placing components other than the CoW dies (e.g., the first package components 107), such as the second package components 109, on the lower surface 105B of the substrate 105, space utilization can be improved, thereby realizing a compact integrated circuit system. However, because the second package components 109 (e.g., VRMs or other possible components) beneath the substrate 105 are not directly attached to a heat sink (e.g., the heat sink 230 located on top of the semiconductor package 100, as shown in FIG. 1), the heat generated by the second package components 109 during operation cannot be effectively dissipated. This causes thermal issues in the second package components 109 or even in the entire package. Therefore, in accordance with some embodiments of the disclosure, the semiconductor package 100 further includes a double-sided heat dissipation module 200 (see FIG. 1) that can solve the above thermal issues.

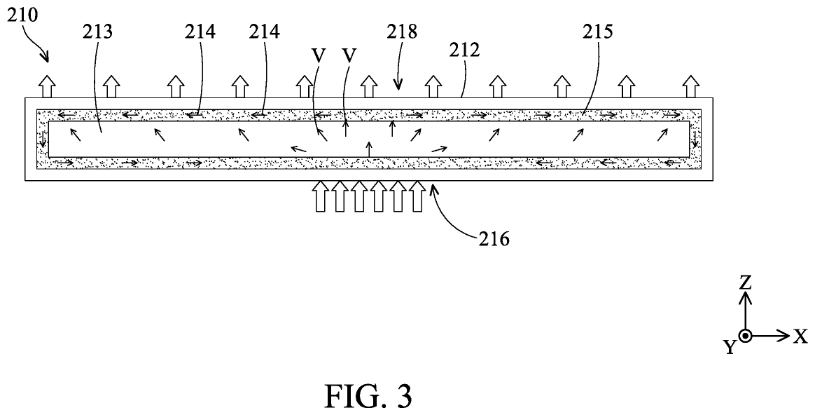

As shown in FIG. 1, the double-sided heat dissipation module 200 includes a first (or upper) heat spreader 210 located above the 3D-IC package module 103 (e.g., located on the side of the 3D-IC package module 103 near the first package components 107). In the present embodiment, the first heat spreader 210 is a heat spreader in the form of a vapor-chamber, so it is also referred to as the first (or upper) vapor-chamber (VC) heat spreader 210 herein. The internal structure and working principle of the first VC heat spreader 210 will be described in detail below with reference to FIG. 3. The first VC heat spreader 210 may have a substantially flat plate structure, and may be thermally coupled to (e.g., in thermal contact with) the first package components 107 so that the heat generated by the first package components 107 can be rapidly spread across the first VC heat spreader 210 in a two-dimensional manner (e.g., in the x-y plane) to prevent the first package components 107 from forming localized hot spots.

In some embodiments, the bottom surface 210A of the first VC heat spreader 210 is attached to (e.g., in thermal contact with) the first package components 107 via one or more first thermal interface materials (TIMs) 201. The first thermal interface material(s) 201 may be applied to the bottom surface 210A of the first VC heat spreader 210 or the top surfaces of the first package components 107 in order to provide a thermal interface between the first package components 107 and the overlying first VC heat spreader 210. In some embodiment, the first thermal interface material(s) 201 may have a thermal conductivity (e.g., “k value”) in Watts per meter-Kelvin (W/mK) of between about 1 W/mK and about 30 W/mK, such as about 4 W/mK. However, any suitable value of thermal conductivity may be used.

In some embodiments, the first thermal interface material 201 may be a metal-based thermal paste containing silver, nickel, or aluminum particles suspended in the silicone grease. In other embodiments, non-electrically conductive, ceramic-based pastes, filled with ceramic powders such as beryllium oxide, aluminum nitride, aluminum oxide, or zinc oxide, may be applied. In other embodiments, the first thermal interface material 201 may be a solid material rather than a paste with a consistency similar to gels or greases. In such embodiments, the first thermal interface material 201 may be a thin sheet of a thermally conductive, solid material, such as indium, nickel, silver, aluminum, combinations and alloys of these, or other suitable thermally conductive solid materials. In some embodiments, the first thermal interface material(s) 201 may be formed by spin-on coating, printing, placement, physical vapor deposition (PVD) or other suitable formation processes. In some embodiments, the first thermal interface material(s) 201 may be formed to have a thickness (in the z-direction) of between about 20 μm and about 200 μm, such as about 60 μm. However, any other suitable thickness may also be used.

In some embodiments, the first VC heat spreader 210 may have a protrusion 211 protruding from the bottom surface 210A of the first VC heat spreader 210 to physically and thermally contact the first thermal interface material(s) 201 above the first package components 107. The protrusion 211 is formed to compensate for the distance between the bottom surface 210A of the first VC heat spreader 210 and the top surfaces of the first package components 107, so that the amount of the first thermal interface material(s) 201 can be reduced. In some embodiments, the protrusion 211 has a cross-sectional shape and dimension (e.g., area) corresponding to the cross-sectional shape and dimension of the outmost boundary of all first package components 107, as shown in FIG. 2. In some alternative embodiments, other numbers (e.g., two or more) and other arrangements of the protrusions 211 are possible, depending on the arrangement of the first package components 107. In other embodiments, the protrusion 211 is not formed.

FIG. 3 schematically shows the internal structure of the first VC heat spreader 210 in FIG. 1 and the working principle of the first VC heat spreader 210 during operation, in accordance with some embodiments. It should be noted that the protrusion 211 of the first VC heat spreader 210 is not shown in FIG. 3 for the sake of simplicity. As shown in FIG. 3, the first VC heat spreader 210 includes an outer shell 212 that encloses, hermetically seals, and defines a cavity between the inner walls of the outer shell 212, thereby providing a vapor-chamber 213 (sometimes also referred to as a vacuum chamber) within the first VC heat spreader 210. The outer shell 212 may include materials that possess a high thermal conductivity and a low coefficient of thermal expansion (CTE). In some embodiments, the outer shell 212 includes a material such as copper, copper alloy, copper tungsten (CuW), or aluminum-silicon-carbide (AlSiC). Other suitable materials for the outer shell 212 may also be used so long as the material possesses at least a low CTE and high thermal conductivity.

The thickness of the outer shell 212 of the first VC heat spreader 210 depends on several factors including, but not limited to, the heat dissipation rate of the first package components 107 of the 3D-IC package module 103, the surface area of the first package components 107, the thermal conductivity of the material of the outer shell 212, the presence of an external heat sink, and the desired size of the semiconductor package 100. In some embodiments, the outer shell 212 may include sheets of thermally conductive material having a substantially uniform thickness. In other embodiments, the outer shell 212 may include sheets of thermally conductive material having different thicknesses. However, any suitable thermally conductive material and any suitable thickness variation may also be used.

In some embodiments, the dimensions of the vapor-chamber 213 may be uniform throughout the first VC heat spreader 210. For example, the vapor-chamber 213 may have the same height (in the z-direction), the same length (in the x-direction), and the same depth (in the y-direction) throughout the first VC heat spreader 210. In other embodiments, one or more of the dimensions of the vapor-chamber 213 may be varied throughout the first VC heat spreader 210. For example, the vapor-chamber 213 may have one or more different heights, different lengths, and different depths at different portions within the first VC heat spreader 210. In some embodiments, the vapor-chamber 213 of the first VC heat spreader 210 may have a height of between about 2 mm and about 4 mm, such as about 3 mm. However, any suitable heights or dimensions may also be used.

In some embodiments, the vapor-chamber 213 sealed within the first VC heat spreader 210 contains an evaporating and condensing liquid such as a two-phase vaporizable liquid, which serves as a working fluid (WF) 214 for the first VC heat spreader 210. The working fluid 214 is a liquid (e.g., freon, wafer, alcohol, etc.) that possesses a relatively high latent heat of vaporization in order to disperse heat away from the first package components 107 (see FIG. 1). As shown in FIG. 3, the first VC heat spreader 210 further includes a substantially planar wick layer 215 for receiving the working fluid 214. In some embodiments, the wick layer 215 may be housed and sealed within the outer shell 212 and positioned substantially along all inner walls of the outer shell 212 defining the vapor-chamber 213. In other embodiments, the wick layer 215 may be positioned substantially along the inner surfaces of the bottom wall (e.g., facing the first package components 107) of the outer shell 212. The wick layer 215 may be made by weaving metal wires that have a large amount of pores (not specifically shown) therein, to generate capillary force for transferring the working fluid 214. Alternatively, the wick layer 215 can also be made by other methods (e.g., sintering metal power). In some embodiments, the wick layer 215 may have an average thickness of about 0.1 mm to about 0.5 mm, although any suitable thickness may also be used.

In operation, the first VC heat spreader 210 works to expel heat generated from the first package components 107 of the 3D-IC package module 103 through one or more areas of thermal contact 216 (e.g., a heat input area 216) maintained within the first TIMs 201 (see FIG. 1). As the first VC heat spreader 210 operates and works to conduct and expel heat away from the first package components 107, the working fluid 214 contained in the wick layer 215 corresponding to the one or more areas of thermal contact 216 (e.g., the heat input area 216) of the first VC heat spreader 210 is heated and vaporizes. The vapor V of the working fluid 214 then spreads to fill the vapor-chamber 213 within the first VC heat spreader 210, and wherever the vapor V comes into contact with a surface of the vapor-chamber 213 that is cooler than the working fluid 214's latent heat of vaporization, heat is expelled through the cooler surface (e.g., the heat rejection area 218, which corresponds to the top surface 210B of the first VC heat spreader 210) of vapor-chamber 213 and the vapor V condenses back to its liquid form of the working fluid 214. Once condensed, the working fluid 214 reflows to the area of thermal contact 216 via a capillary force generated by the wick layer 215. Thereafter, the working fluid 214 frequently vaporizes and condenses to form a circulation to expel the heat generated by the first package components 107 of the 3D-IC package module 103. This structure effectively spreads thermal energy across the first VC heat spreader 210 so that heat generated by the first package components 107 may be drawn off via the heat input area 216 and dissipated via the heat rejection area 218 to the surrounding environment in a highly efficient manner (e.g., in cases where a fan module (not shown) provides airflow F flowing over the first VC heat spreader 210 for air cooling, as shown in FIG. 1). Therefore, the thermal issues (e.g., localized hot spots) of the first package components 107 can be avoided.

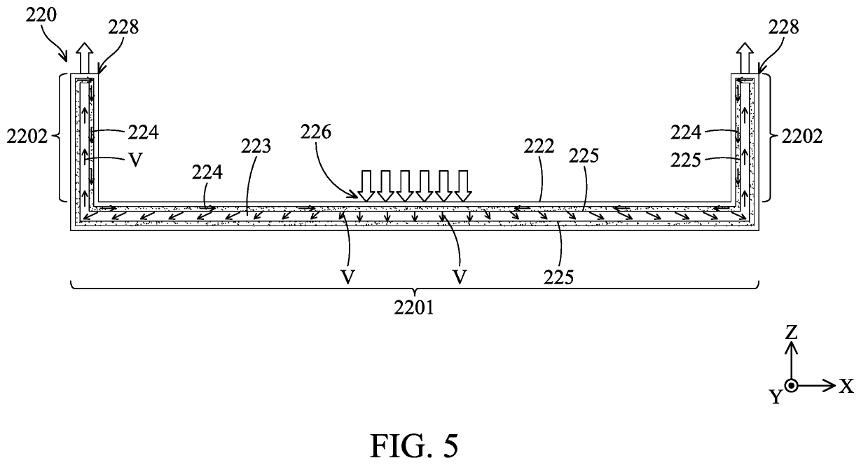

The double-sided heat dissipation module 200 also includes a second (or lower) heat spreader 220 located below the 3D-IC package module 103 (e.g., located on the side of the 3D-IC package module 103 near the second package components 109), as shown in FIG. 1. In the present embodiment, the second heat spreader 220 is a heat spreader in the form of a vapor-chamber, so it is also referred to as the second (or lower) vapor-chamber (VC) heat spreader 220 herein. The internal structure and working principle of the second VC heat spreader 220 will be described in detail below with reference to FIG. 5. Similarly, the second VC heat spreader 220 (e.g., its main body 2201) may have a substantially flat plate structure, and may be thermally coupled to (e.g., in thermal contact with) the second package components 109 so that the heat generated by the second package components 109 can be rapidly spread across the second VC heat spreader 220 in a two-dimensional manner (e.g., in the x-y plane) to prevent the second package components 109 from forming localized hot spots.

In some embodiments, the top surface 220A of the second VC heat spreader 220 (e.g., the main body 2201) is attached to (e.g., in thermal contact with) the second package components 109 via one or more second thermal interface materials (TIMs) 203. The second thermal interface material(s) 203 may be applied to the top surface 220A of the second VC heat spreader 220 or the bottom surfaces of the second package components 109 in order to provide a thermal interface between the second package components 109 and the underlying second VC heat spreader 220. In some embodiments, the second thermal interface material(s) 203 may have a thermal conductivity (e.g., “k value”) in Watts per meter-Kelvin (W/mK) of between about 1 W/mK and about 30 W/mK, such as about 4 W/mK, similar to the thermal conductivity of the first TIMs 201. However, any suitable value of thermal conductivity may be used. In some embodiments, the second thermal interface material 203 may be the same material as the first thermal interface material 201 described above, although the second thermal interface material 203 may also be a different material than the first thermal interface material 201. The dimension (e.g., thickness) and formation method of the second thermal interface material 203 may be the same as or similar to those of the first thermal interface material 201, and are not repeated here.

In some embodiments, the second VC heat spreader 220 may have a protrusion 221 protruding from the top surface 220A of the second VC heat spreader 220 to physically and thermally contact the second thermal interface material(s) 203 below the second package components 109. The protrusion 221 is formed to compensate for the distance between the top surface 220A of the second VC heat spreader 220 and the bottom surfaces of the second package components 109, so that the amount of second thermal interface materials 203 used can be reduced. In some embodiments, the protrusion 221 may have a cross-sectional shape and dimension (e.g., area) corresponding to the cross-sectional shape and dimension of the outmost boundary of all second package components 109, as shown in FIG. 4. In some alternative embodiments, there may be another number (e.g., two or more) of protrusions 221, in another arrangement, depending on the number and/or arrangement of second package components 109. In other embodiments, the protrusion 221 is not formed.

In some embodiments, the second VC heat spreader 220 is placed in such a way that the bottom surface 220B of the second VC heat spreader 220 (e.g., the main body 2201) is in direct contact with the top surface of the system board 101, as shown in FIG. 1. The second package components 109 can be separated from the system board 101 by the second VC heat spreader 220. In addition, the 3D-IC package module 103 may further include I/O interface connectors 115 (e.g., sockets, see FIG. 1) disposed on the lower surface 105B of the substrate 105 for electrically connecting the 3D-IC package module 103 to the system board 101, in some cases. In such cases, the I/O interface connectors 115 may be arranged along the edges of the substrate 105 and outside the second VC heat spreader 220 in a plan view (as shown in FIG. 4), therefore the second VC heat spreader 220 will not interfere with the connection between the 3D-IC package module 103 and the system board 101 through the I/O interface connectors 115. It should be noted that the arrangement of the I/O interface connectors 115 illustrated in FIG. 4 is merely a non-limiting example, and other arrangements may also be used.

In the present embodiment, the difference between the second VC heat spreader 220 and the first VC heat spreader 210 is that opposite ends (in the x-direction) of the main body 2201 of the second VC heat spreader 220 are respectively connected with a vertically extending heat-transfer channel 2202 (see FIG. 1). In other embodiments, other numbers (e.g., one or more than two) and other arrangements/configurations (e.g., locations) of the heat-transfer channels 2202 may also be used, and are fully intended to be included within the scope of the present disclosure. Each heat-transfer channel 2202 may extend vertically upward from the top surface 220A of the main body 2201 toward the bottom surface 210A of the first VC heat spreader 210. In some embodiments, the heat-transfer channel 2202 may have a height (in the z-direction) that is substantially equal to the vertical distance between the bottom surface 210A of the first VC heat spreader 210 and the top surface 220A of second VC heat spreader 220 (e.g., main body 2201).

In some embodiments, distal ends of the heat-transfer channels 2202 may be thermally coupled to (e.g., in thermal contact with) first VC heat spreader 210 (e.g., via one or more third thermal interface materials (TIMs) 205) to allow heat energy to be transferred from the second VC heat spreader 220 to the first VC heat spreader 210 through the heat-transfer channels 2202, in cases where a fan module (not shown) provides airflow F flowing over the first VC heat spreader 210 for air cooling (see FIG. 1). The third TIM 205 may be the same as or similar to the first TIM 201 or second TIM 203 described above, and thus not repeated here.

In some embodiments, the main body 2201 and the heat-transfer channels 2202 of the second VC heat spreader 220 are an integrally formed continuous structure (i.e., there is no bonding interface, such as adhesive, between the main body 2201 and each heat-transfer channel 2202, and the vapor-chamber extends continuously throughout the structure). In this regard, each of the heat-transfer channels 2202 is also in the form of a vapor-chamber, so it is also referred to as the vapor-chamber (VC) heat-transfer channel 2202 herein. Furthermore, in a plan view, the depth dimension W1 (in the y-direction) of the main body 2201 and the depth dimension W2 (in the y-direction) of the heat-transfer channels 2202 may be the same as shown in FIG. 4, but the disclosure is not limited thereto. In some embodiments, each VC heat-transfer channel 2202 of the second VC heat spreader 220 may be formed by applying mechanical force to bend a portion of one end of a long flat vapor-chamber (VC) 90 degrees. However, any other suitable methods for forming the VC heat-transfer channel 2202 may also be used.

FIG. 5 schematically shows the internal structure of the second VC heat spreader 220 (with upwardly extending VC heat-transfer channels 2202) in FIG. 1 and the working principle of the second VC heat spreader 220 during operation, in accordance with some embodiments. It should be noted that the protrusion 221 of the second VC heat spreader 220 is not shown in FIG. 5 for the sake of simplicity. As shown in FIG. 5, the second VC heat spreader 220 includes an outer shell 222 that encloses, hermetically seals, and defines a cavity between inner walls of the outer shell 222, thereby providing a vapor-chamber 223 (sometimes also referred to as a vacuum chamber) within the second VC heat spreader 220. The details (e.g., including material, thickness, etc.) of the outer shell 222 of the second VC heat spreader 220 may be similar to those of the outer shell 212 of the first VC heat spreader 210 described above, except that the outer shell 222 further has two vertical extending portions (not otherwise labeled) corresponding to the VC heat-transfer channels 2202.

As shown in FIG. 5, the vapor-chamber 223 within the second VC heat spreader 220 continuously extends from the main body 2201 to the VC heat-transfer channels 2202 of the second VC heat spreader 220. In some embodiments, the dimensions of the vapor-chamber 223 may be uniform throughout the second VC heat spreader 220. For example, the vapor-chamber 223 may have the same height (in the z-direction), the same length (in the x-direction), and the same depth (in the y-direction) throughout the horizontally extending main body 2201, and may have the same channel width (in the x-direction) and the same depth (in the y-direction) throughout the vertically extending VC heat-transfer channels 2202. In other embodiments, one or more of the dimensions of the vapor-chamber 223 may be varied throughout the second VC heat spreader 220. For example, the vapor-chamber 223 may have one or more different heights, different lengths, different channel widths, and different depths at different portions within the second VC heat spreader 220. In some embodiments, the vapor-chamber 223 of the second VC heat spreader 220 may have a height or a channel width (i.e., the height of the main body 2201 or the channel width of each VC heat-transfer channel 2202) of between about 2 mm and about 4 mm, such as about 3 mm. However, any suitable heights or dimensions may also be used.

In some embodiments, the vapor-chamber 223 sealed within the second VC heat spreader 220 contains an evaporating and condensing liquid such as a two-phase vaporizable liquid, which serves as a working fluid (WF) 224 for the second VC heat spreader 220. The working fluid 224 is a liquid (e.g., freon, wafer, alcohol, etc.) that possesses a relatively high latent heat of vaporization in order to disperse heat away from the second package components 109 (see FIG. 1). As shown in FIG. 5, the second VC heat spreader 220 further includes a substantially planar wick layer 225 for receiving the working fluid 224. In some embodiments, the wick layer 225 may be housed and sealed within the outer shell 222 and positioned substantially along all inner walls of the outer shell 222 defining the vapor-chamber 223. In other embodiments, the wick layer 225 may be positioned substantially along the inner surfaces of the top wall (e.g., facing the second package components 109) of the outer shell 222 corresponding to the main body 2201 and along the inner surfaces of the inner walls (e.g., facing the second package components 109) of the outer shell 222 corresponding to the heat-transfer channels 2202. The material, structure, thickness, and formation method of the wick layer 225 may be the same as or similar to those of the wick layer 215 of the first VC heat spreader 210 described above, and thus not repeated here.

In operation, the second VC heat spreader 220 works to expel heat generated from the second package components 109 of the 3D-IC package module 103 through one or more areas of thermal contact 226 (e.g., a heat input area 226) maintained within the second TIMs 203 (see FIG. 1). As the second VC heat spreader 220 operates and works to conduct and expel heat away from the second package components 109, the working fluid 224 contained in the wick layer 225 corresponding to the one or more areas of thermal contact 226 (e.g., the heat input area 226) of the second VC heat spreader 220 is heated and vaporizes. The vapor V of the working fluid 224 then spreads to fill the vapor-chamber 223 within the second VC heat spreader 220 (including the main body 2201 and the heat-transfer channels 2202), and wherever the vapor V comes into contact with a surface of the vapor-chamber 223 that is cooler than the working fluid 224's latent heat of vaporization, heat is expelled through the cooler surface (e.g., the heat rejection area 228, such as one or more areas of thermal contact 228 maintained within the third TIMs 205 (see FIG. 1)) of vapor-chamber 223 and the vapor V condenses back to its liquid form of the working fluid 224. Once condensed, the working fluid 224 reflows to the area of thermal contact 226 via a capillary force generated by the wick layer 225. Thereafter, the working fluid 224 frequently vaporizes and condenses to form a circulation to expel the heat generated by the second package components 109 of the 3D-IC package module 103. This structure effectively spreads thermal energy across the second VC heat spreader 220 so that heat generated by the second package components 109 may be drawn off via the heat input area 226 and dissipated via the heat rejection area 228 to the surrounding environment (e.g., transferred to the first VC heat spreader 210 via the third TIMs 205) in a highly efficient manner. The first VC heat spreader 210 then further dissipates the heat to the external environment, such as through air cooling. Therefore, the thermal issues (e.g., localized hot spots) of the second package components 109 can be avoided.

By disposing the first VC heat spreader 210 and the second VC heat spreader 220 to be in thermal contact with the first package components 107 and the second package components 109 of the 3D-IC package module 103, respectively, and thermally coupling the first and second VC heat spreaders 210 and 220 through the VC heat-transfer channels 2202 (as described above), the heat generated by the package components mounted on both sides of the substrate 105 can be effectively dissipated simultaneously through the double-sided heat dissipation module 200. This reduces thermal issues on those packaged components and the entire package, thereby improving product reliability.

In some embodiments, the double-sided heat dissipation module 200 further includes a heat sink 230 (e.g., fin structures), as shown in FIG. 1. The heat sink 230 may be made of a higher thermal conductivity material (e.g., copper), and may be bonded (e.g., soldered) to the side (e.g., the top surface 210B) of the first VC heat spreader 210 opposite the 3D-IC package module 103 to improve the heat dissipation efficiency of the double-sided heat dissipation module 200. The heat sink 230 promotes heat dissipation by allowing airflow provided by a fan module (not shown) to flow through the fin structures of the heat sink 230 with a larger surface area. It should be noted that the structure of the heat sink 230 illustrated in FIG. 1 is merely a non-limiting example, and other structures may also be used. In other embodiments, the heat sink 230 is not present.

FIG. 1 further illustrates a plurality of screws S provided to secure the first VC heat spreader 210 and the second VC heat spreader 220 together and to secure the double-sided heat dissipation module 200 to the system board 101, in accordance with some embodiments. For example, the screws S may pass through the corresponding openings O1 (see FIG. 2) in the first VC heat spreader 210, the corresponding openings O2 (see FIG. 4) of the second VC heat spreader 220, and the corresponding openings (not specifically shown) of the system board 101 to secure these components together. In some embodiments, each of the screws S is a spring screw, which can provide proper force on the “sandwich-like” heat dissipation module 200 for better coverage and contact of the TIMs (e.g., 201, 203 and 205) between the VC heat spreaders (e.g., 210 and 220) and between the VC heat spreaders (e.g., 210 and 220) and the respective package components (e.g., 107 and 109). In other embodiments, other suitable fastening means may also be used.

FIG. 1 further illustrates that the 3D-IC package module 103 includes an upper ring 111 and a lower ring 113 attached to the upper surface 105A and the lower surface 105B of the substrate 105, respectively (e.g., via adhesives, not shown), in accordance with some embodiments. The upper ring 111 and the lower ring 113 may be arranged along the edges of the substrate 105 and may encircle the package components (e.g., 107 and 109) in a plan view. In some embodiments, each of the upper ring 111 and the lower ring 113 may be a stiffener ring used to reduce warpage for the substrate 105. Example of the material of the upper ring 111 and the lower ring 113 may include metals such as copper, stainless steel, stainless steel/Ni, and the like, but are not limited thereto. In the illustrated embodiment, a gap separates the upper ring 111 from the upper VC heat spreader 210, and a gap separates the lower ring 113 from the lower VC heat spreader 220, although additional TIMs may also be applied to the one or more of the gaps for better thermal conduction and heat dissipation in other embodiments.

Other features and processes may also be included. For example, testing structures may be included to aid in the verification testing of the 3D packaging or 3D-IC devices. The testing structures may include, for example, test pads formed in a redistribution layer or on a substrate that allows the testing of the 3D packaging or 3D-IC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

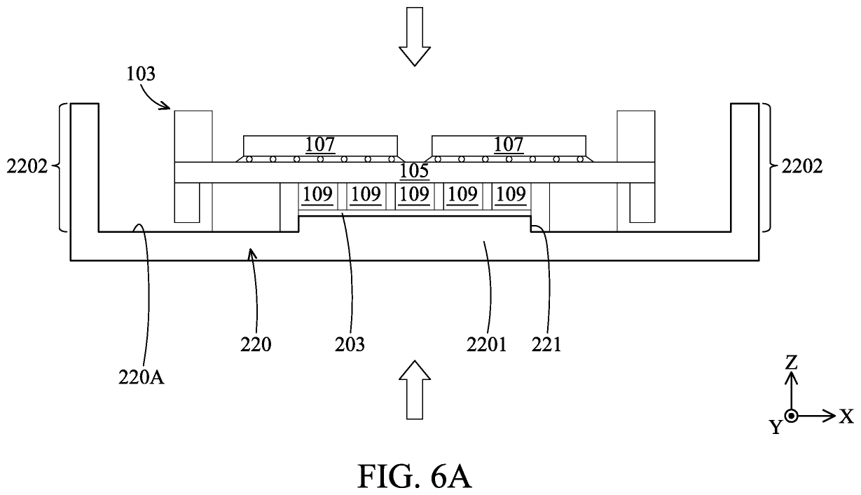

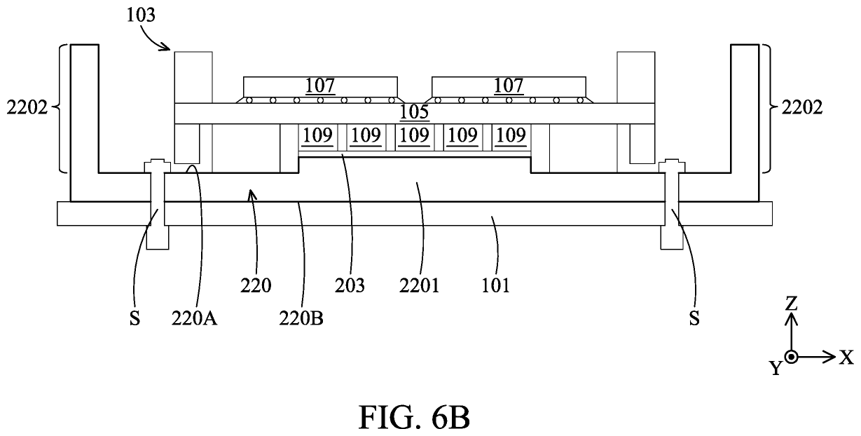

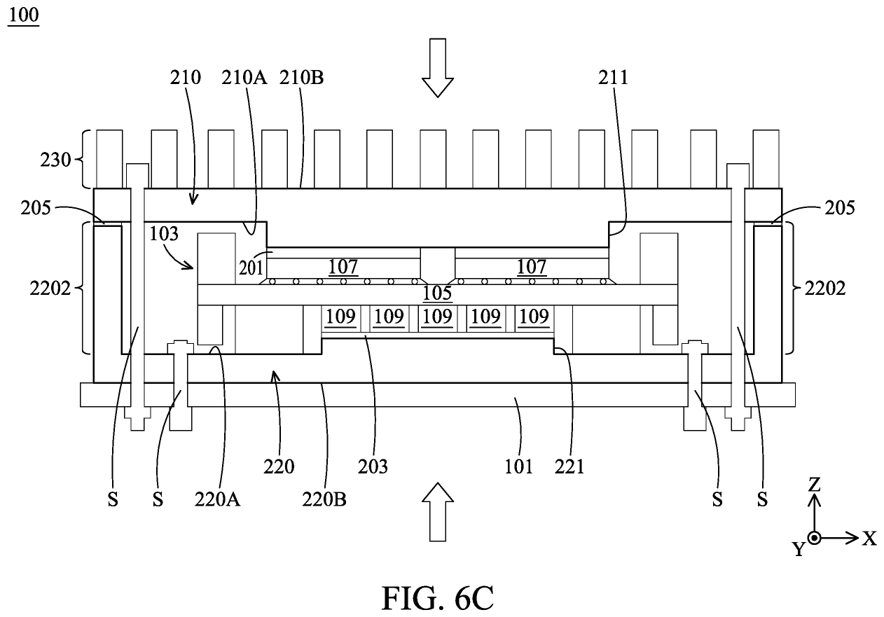

FIGS. 6A to 6C illustrate vertical cross-sectional views of intermediate steps of forming the semiconductor package 100 (e.g., see FIG. 6C) with the double-sided heat dissipation module 200 in FIG. 1, in accordance with some embodiments. In FIG. 6A, after forming or obtaining the 3D-IC package module 103 and the second VC heat spreader 220, one or more second TIMs 203 may be applied as discussed above. Thereafter, the 3D-IC package module 103 and the second VC heat spreader 220 may be pressed against each other, so that the 3D-IC package module 103 (e.g., the second package components 109) and the second VC heat spreader 220 are bonded and secured together through the second TIMs 203.

In FIG. 6B, the assembly of the 3D-IC package module 103 and the second VC heat spreader 220 is placed on the system board 101, and then secured onto the system board 101 by using a plurality of screws S (e.g., spring screws) passing through the second VC heat spreader 220 and the system board 101.

In FIG. 6C, after forming or obtaining the first VC heat spreader 210 (which may or may not have a heat sink 230 (e.g., fin structures) attached thereto, in some cases), one or more first TIMs 201 and third TIMs 205 may be applied as discussed above. The assembly of the 3D-IC package module 103, the second VC heat spreader 220, and the system board 101 and the first VC heat spreader 210 may then be pressed against each other, so that the first VC heat spreader 210 and the 3D-IC package module 103 (e.g., the first package components 107) are bonded and secured together through the first TIMs 201, and the first VC heat spreader 210 and the VC heat-transfer channels 2202 of the second VC heat spreader 220 are bonded and secured together through the third TIMs 205. Thereafter, a plurality of additional screws S (e.g., spring screws) may be provided to pass through the first VC heat spreader, the second VC heat spreader 220, and the system board 101, which facilitates better coverage and contact of the TIMs (e.g., 201, 203 and 205) between the VC heat spreaders (e.g., 210 and 220) and between the VC heat spreaders (e.g., 210 and 220) and the respective package components (e.g., 107 and 109).

It should be noted that the assembly order illustrated in FIGS. 6A to 6C is merely a non-limiting example, and other assembly orders may also be used.

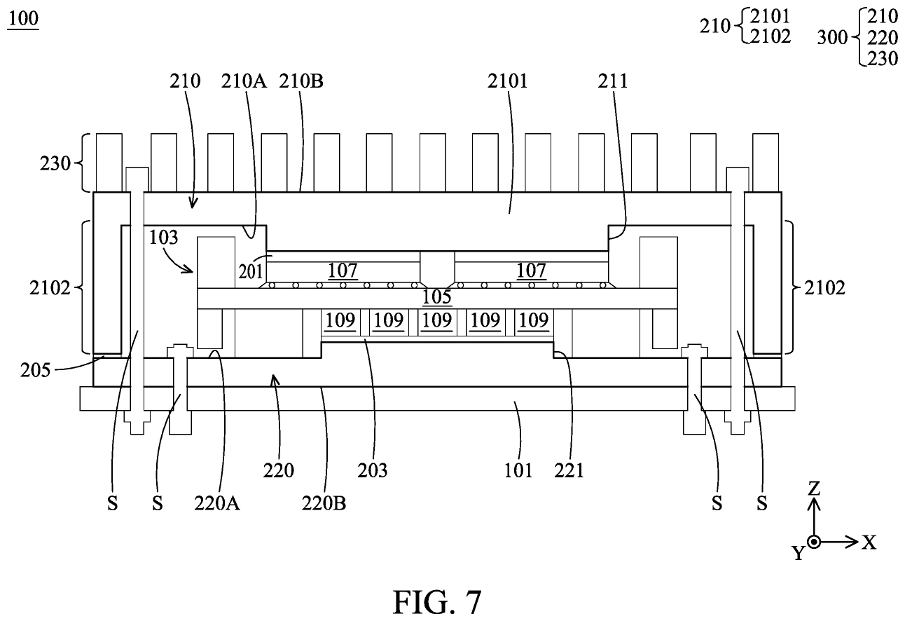

FIG. 7 is a vertical cross-sectional view of a first alternative of a semiconductor package 100, in accordance with some embodiments. In the first alternative of the semiconductor package, the double-sided heat dissipation module 200 is replaced with a double-sided heat dissipation module 300, while other features are the same as the original embodiment shown in FIGS. 1 to 5. The double-sided heat dissipation module 300 differs from the double-sided heat dissipation module 200 in that the vertical extending VC heat-transfer channels 2202 of the second VC heat spreader 220 are not present, and vertical extending VC heat-transfer channels 2102 are connected to opposite ends of the main body 2101 of the first VC heat spreader 210 (e.g., they may extend vertically downwardly from the bottom surface 210A of the main body 2101 of the first VC heat spreader 210 toward the top surface 220A of the second VC heat spreader 220). The structure and other details of the VC heat-transfer channels 2102 of the first VC heat spreader 210 may be similar to those of the VC heat-transfer channels 2202 of the second VC heat spreader 220 illustrated in FIGS. 1 to 5, and thus not repeated here. In the present embodiments, the third TIMs 205 may be applied between the bottom surfaces of the distal ends of the VC heat-transfer channels 2102 and the top surface 220A of the second VC heat spreader 220.

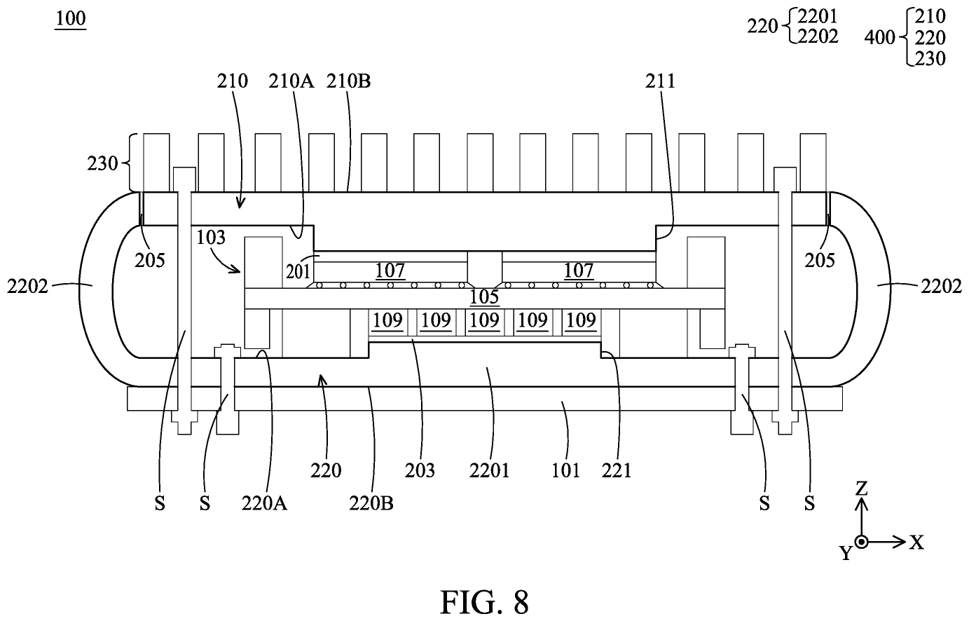

FIG. 8 is a vertical cross-sectional view of a second alternative of a semiconductor package 100 with a double-sided heat dissipation module 400, in accordance with some embodiments. In the second alternative of the semiconductor package, the double-sided heat dissipation module 200 is replaced with a double-sided heat dissipation module 400, while other features are the same as the original embodiment shown in FIGS. 1 to 5. The double-sided heat dissipation module 400 differs from the double-sided heat dissipation module 200 in that each of the VC heat-transfer channels 2202 extended from the second VC heat spreader 220 is changed to a C shape instead of a vertical straight shape. In alternative embodiments, the VC heat-transfer channels 2202 may have a U shape or some other suitable curved shape. In some embodiments, each C-shaped VC heat-transfer channel 2202 may be formed by applying mechanical force to bend a portion of one end of a long flat vapor-chamber (VC). However, any other suitable methods for forming the C-shaped VC heat-transfer channel 2202 may also be used. In other embodiments, the C-shaped VC heat-transfer channels may also be connected to (e.g., extend continuously from) the first VC heat spreader 210 instead of the second VC heat spreader 220 (similar to the embodiment shown in FIG. 7). In the present embodiment, the third TIMs 205 may be applied between the distal ends of the C-shaped VC heat-transfer channel 2202 and the sidewalls of the first VC heat spreader 210. In different embodiments, any other suitable shapes may o be used.

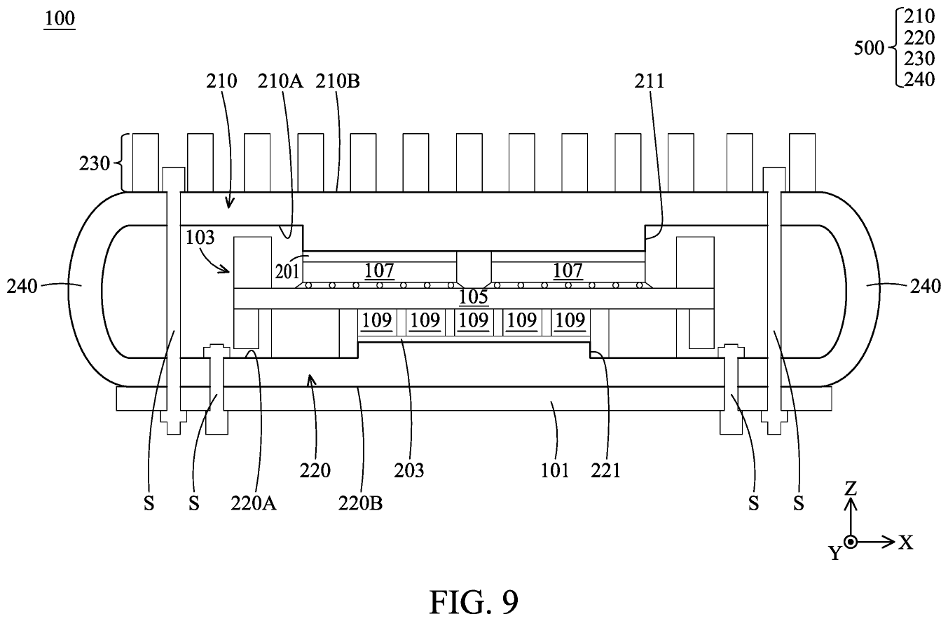

FIG. 9 is a vertical cross-sectional view of a third alternative of a semiconductor package 100 with a double-sided heat dissipation module 500, in accordance with some embodiments. In the third alternative of the semiconductor package, the double-sided heat dissipation module 200 is replaced with a double-sided heat dissipation module 500, while other features are the same as the original embodiment shown in FIGS. 1 to 5. The double-sided heat dissipation module 500 differs from the double-sided heat dissipation module 200 in that the first VC heat spreader 210 and the second VC heat spreader 220 are connected by two VC heat-transfer channels 240 (which may be similar to the VC heat-transfer channels 2102 or 2202 described above) are opposite ends, wherein one end of each VC heat-transfer channel 240 is directly (e.g., physically) connected to the corresponding end of the first VC heat spreader 210, and the other end is directly (e.g., physically) connected to the corresponding end of the second VC heat spreader 220. In this regard, the first VC heat spreader 210, the second VC heat spreader 220, and the two VC heat-transfer channels 240 are an integrally formed continuous structure (e.g., there is no bonding interface, such as adhesive, between these components, and the vapor-chamber extends continuously throughout the structure), which may be formed by using a soldering process to connect these components. Other suitable formation processes may also be used.

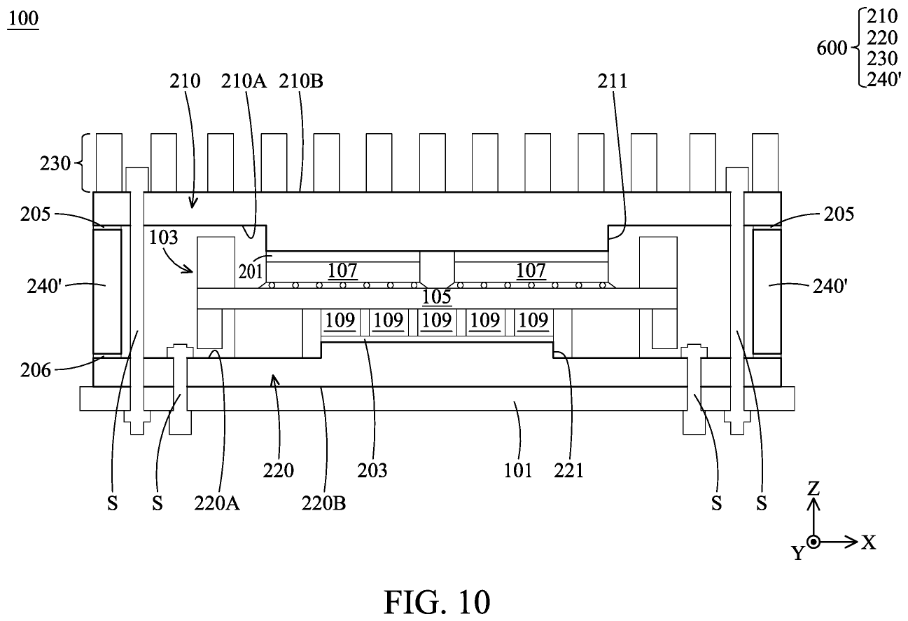

FIG. 10 is a vertical cross-sectional view of a fourth alternative of a semiconductor package 100 with a double-sided heat dissipation module 600, in accordance with some embodiments. In the fourth alternative of the semiconductor package, the double-sided heat dissipation module 200 is replaced with a double-sided heat dissipation module 600, while other features are the same as the original embodiment shown in FIGS. 1 to 5. The double-sided heat dissipation module 600 differs from the double-sided heat dissipation module 200 in that the first VC heat spreader 210 and the second VC heat spreader 220 are connected by two separate VC heat-transfer channels 240′ (which may be similar to the VC heat-transfer channels 2102 or 2202 described above) on opposite ends, wherein one end of each VC heat-transfer channel 240 is thermally coupled to the corresponding end of the first VC heat spreader 210 via a third TIM 205, and the other end is thermally coupled to the corresponding end of the second VC heat spreader 220 via a fourth TIM 206 (which may be similar to the first, second or third TIM 201, 203 or 205 described above).

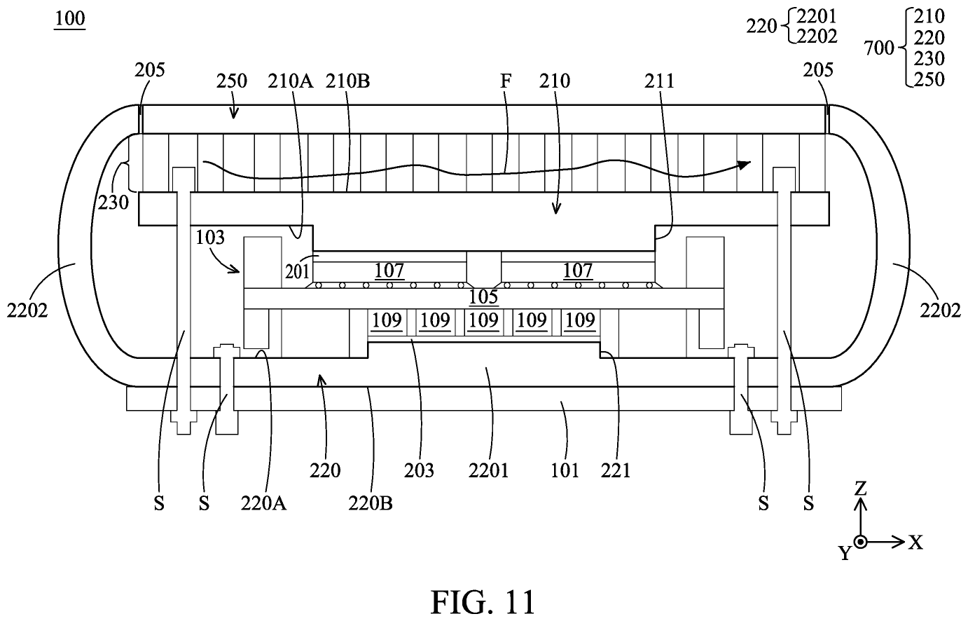

FIG. 11 is a vertical cross-sectional view of a fifth alternative of a semiconductor package 100 with a double-sided heat dissipation module 700, in accordance with some embodiments. In the fifth alternative of the semiconductor package, the double-sided heat dissipation module 200 is replaced with a double-sided heat dissipation module 700, while other features are the same as the original embodiment shown in FIGS. 1 to 5. The double-sided heat dissipation module 700 differs from the double-sided heat dissipation module 200 in that a third (or top) vapor-chamber (VC) heat spreader 250 (which may be similar to the first VC heat spreader 210 or the second VC heat spreader 220 described above) is placed above and attached to the heat sink 230. In some embodiments, the third VC heat spreader 250 may be in thermal contact with the fin structures of the heat sink 230 through a thermal interface material (TIM) or through soldering (not shown). In addition, the VC heat-transfer channels 2202 extended from the second VC heat spreader 220 are thermally coupled to the third VC heat spreader 250 instead of the first VC heat spreader 210 via the third TIMs 205.

Through the above configuration, in addition to rapidly dissipating the heat generated by the first package components 107 to the surrounding environment through the first VC heat spreader 210 and/or the heat sink 230 (as mentioned above), the heat generated by the second package components 109 can also be transferred from the second VC heat spreader 220 to the third VC heat spreader 210 through the heat-transfer channels 2202, and then the third VC heat spreader 210 dissipates the heat to the external environment via the heat sink 230 (for example, the heat may be removed by the airflow F flowing through the fin structures of the heat sink 230). Accordingly, the package components (e.g., 107 and 109) mounted on both sides of the substrate 105 of the 3D-IC package module 103 can be effectively dissipated simultaneously through the double-sided heat dissipation module 700. In addition, since the first VC heat spreader 210 and the second VC heat spreader 220 are not thermally coupled, this reduces thermal crosstalk between the first VC heat spreader 210 and the second VC heat spreader 220, thereby improving heat dissipation efficiency.

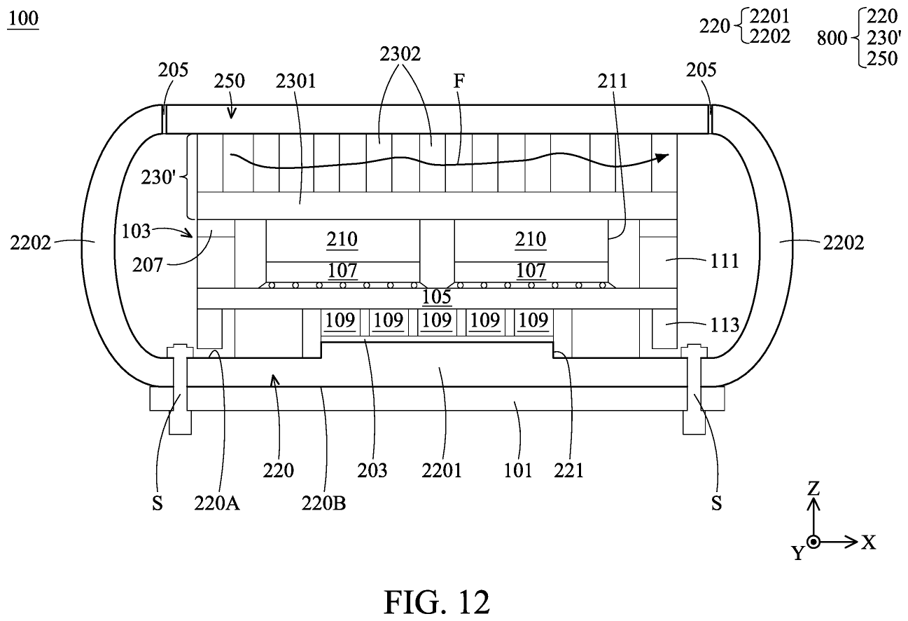

FIG. 12 is a vertical cross-sectional view of a sixth alternative of a semiconductor package 100 with a double-sided heat dissipation module 800, in accordance with some embodiments. In the sixth alternative of the semiconductor package, the double-sided heat dissipation module 200 is replaced with a double-sided heat dissipation module 800, while other features are the same as the original embodiment shown in FIGS. 1 to 5. The double-sided heat dissipation module 800 is similar to the double-sided heat dissipation module 700 illustrated in FIG. 11, except that the first (or upper) VC heat spreader 210 attached to the first package components 107 is omitted. In addition, the heat sink 230′ (e.g., the connection base 2301 supporting the fin structures 2302) is directly attached to (e.g., in thermal contact with) the first package components 107 via one or more first thermal interface materials (TIMs) 201. The double-sided heat dissipation module 800 can also achieve the same or similar heat dissipation effect as the double-sided heat dissipation module 700 of FIG. 11 described above.

FIG. 12 further illustrates that one or more fourth thermal interface materials (TIMs) 207 may be applied between the top surface of the upper ring 111 and the bottom surface of the heat sink 230′ (e.g., the connection base 2301) to enhance thermal conduction and heat dissipation. For example, some heat generated within the 3D-IC package module 103 during operation can also be dissipated to the heat sink 230′ through the upper ring 111 and the fourth TIMs 207 and then dissipated to the external environment. In other embodiments, the fourth TIMs 207 is not present, and a gap separates the upper ring 111 from the upper VC heat spreader 210, similar to the embodiments discussed above with reference to FIG. 1.

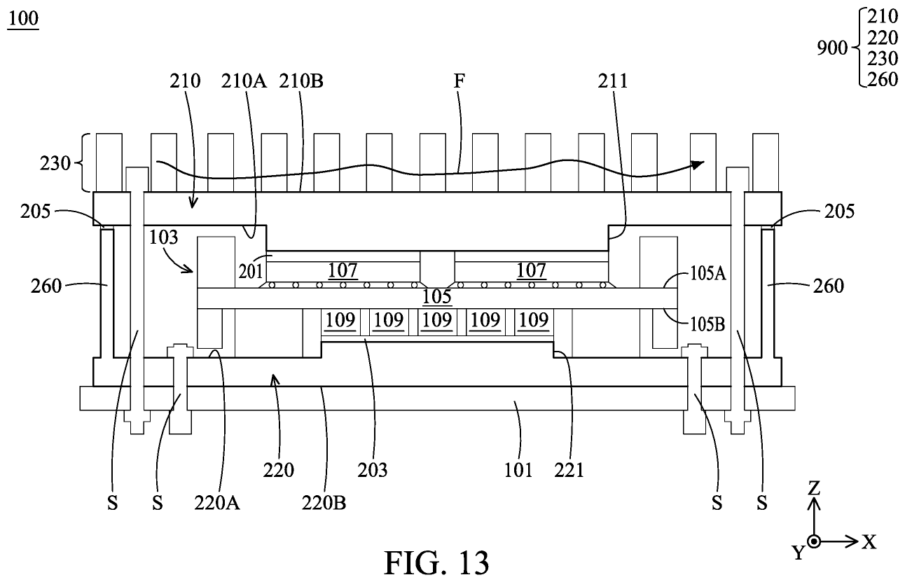

FIG. 13 is a vertical cross-sectional view of a seventh alternative of a semiconductor package 100 with a double-sided heat dissipation module 900, in accordance with some embodiments. In the seventh alternative of the semiconductor package, the double-sided heat dissipation module 200 is replaced with a double-sided heat dissipation module 900, while other features are the same as the original embodiment shown in FIGS. 1 to 5. The double-sided heat dissipation module 900 is similar to the double-sided heat dissipation module 200, except that the VC heat-transfer channels 2202 of the second VC heat spreader 220 are not present, and a plurality of heat-transfer channels 260 in the form of heat-pipes (therefore also referred to herein as heat-pipe (HP) heat-transfer channels 260) are provided to transfer heat from the second VC heat spreader 220 to the first VC heat spreader 210 along their long-axis direction (e.g., the z-direction).

In the present embodiment, the HP heat-transfer channels 260 are bonded (e.g., soldered) to the top surface 220A of the second VC heat spreader 220 such that the second VC heat spreader 220 and the HP heat-transfer channels 260 form a continuous structure (e.g., the second VC heat spreader 220 and the HP heat-transfer channels 260 share a single continuous vapor/vacuum chamber). Distal ends of the HP heat-transfer channels 260 may be thermally coupled to (e.g., in thermal contact with) first VC heat spreader 210 (e.g., via one or more third thermal interface materials (TIMs) 205) to allow heat energy to be transferred from the second VC heat spreader 220 to the first VC heat spreader 210 through the HP heat-transfer channels 260. The double-sided heat dissipation module 900 can also achieve the same or similar heat dissipation effect as the double-sided heat dissipation module 200 of FIGS. 1 to 5 described above.

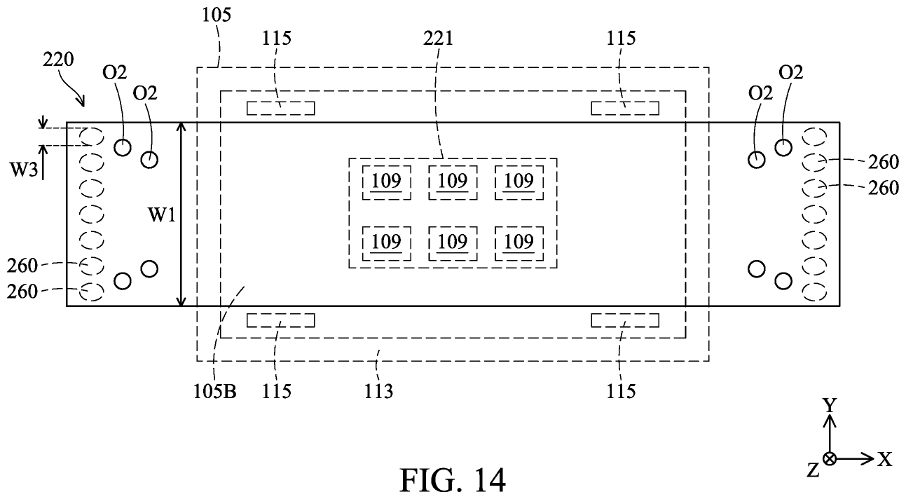

FIG. 14 is a plan view (e.g., a bottom-up view) showing the arrangement of the second integrated circuit devices 109 and the second (or lower) VC heat spreader 220 (and the HP heat-transfer channels 260 attached thereto) over the lower surface 105B of the substrate 105 in FIG. 13, in accordance with some embodiments. As shown in FIG. 14, the HP heat-transfer channels 260 may be arranged along opposite edges of the second VC heat spreader 220. The diameter dimension W3 of each HP heat-transfer channel 260 may be smaller than the depth dimension W1 (in the y-direction) in a plan view. It should be noted that the number and arrangement of the HP heat-transfer channels 260 can be determined according to actual needs, and are not limited to those shown in FIG. 14.

Although the HP heat-transfer channels 260 are shown bonded (e.g., soldered) to the second VC heat spreader 220 in FIG. 14, the HP heat-transfer channels 260 may be bonded (e.g., soldered) to the first VC heat spreader 210 (similar to the embodiment shown in FIG. 7), bonded (e.g., soldered) to both the first VC heat spreader 210 and second VC heat spreader 220 (similar to the embodiment shown in FIG. 9), or may be separate components from the first VC heat spreader 210 and second VC heat spreader 220 (similar to the embodiment shown in FIG. 10) in other embodiments. In other embodiments, the HP heat-transfer channels 260 may be a C-shape or U-shape instead of a vertical straight shape (similar to the embodiment shown in FIG. 8). Any other suitable shapes may also be used.

It should be understood that the structures, configurations and the manufacturing methods of the double-sided heat dissipation module described herein are only illustrative, and are not intended to be, and should not be construed to be, limiting to the present disclosure. Many alternatives and modifications will be apparent to those skilled in the art, once informed by the present disclosure. For example, various features in the above-mentioned different embodiments can be combined arbitrarily (e.g., both the VC-type and HP-type heat-transfer channels can be included in the double-sided heat dissipation module).

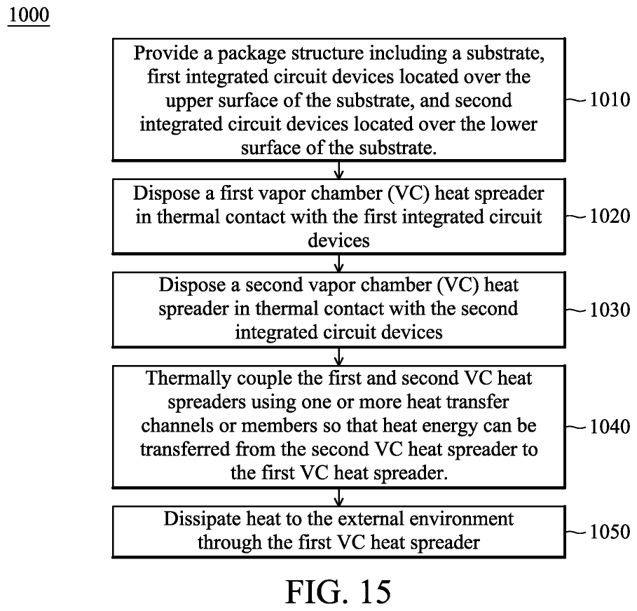

FIG. 15 is a flowchart of a method 1000 of using a double-sided heat dissipation module to dissipate heat from a semiconductor package. In step 1010 of the method 1000, a package structure (e.g., the 3D-IC packaging module 103) is provided, which includes a substrate 105, a plurality of first integrated circuit devices 107 located over the upper surface 105A of the substrate 105, and a plurality of second integrated circuit devices 109 located over the lower surface 105B of the substrate 105. In step 1020 of the method 1000, a first vapor-chamber (VC) heat spreader 210 is disposed in thermal contact with the first integrated circuit devices 107. In step 1030 of the method 1000, a second vapor-chamber (VC) heat spreader 220 is disposed in thermal contact with the second integrated circuit devices 109. In step 1040 of the method 1000, the first and second VC heat spreaders 210 and 220 are thermally connected using one or more heat-transfer channels or members (e.g., 2102, 2202, 240, 240′, 260) so that heat energy can be transferred form the second VC heat spreader 220 to the first VC heat spreader 210. In step 1050 of the method 1000, heat energy is dissipated to the external environment through the first VC heat spreader 210 or an optional heat sink (e.g., 230) attached thereto (e.g., through air cooling).

Embodiments of the double-sided heat dissipation module discussed herein may have advantages. By disposing an upper VC heat spreader and a lower VC heat spreader to be thermally coupled to the first and second package components located on both sides of the substrate/interposer of a 3D-IC package structure, respectively, and thermally coupling the upper and lower VC heat spreaders through one or more heat-transfer channels/members as discussed above, the heat energy generated by the second package components below the substrate during operation can be transferred from the lower VC heat spreader to the upper VC heat spreader, and then dissipated to the external environment through the upper VC heat spreader or an optional heat sink attached thereto. Accordingly, the package components mounted on both sides of the substrate can be effectively dissipated simultaneously, thereby reducing thermal issues on those packaged components and the entire package. As a result, product reliability is improved.

In accordance with some embodiments, a semiconductor package is provided. The semiconductor package includes a substrate having an upper surface and a lower surface, first integrated circuit devices mounted on the upper surface, and second integrated circuit devices mounted on the lower surface. A first heat spreader in the form of a vapor-chamber (VC) is located over the first integrated circuit devices. A second heat spreader in the form of a vapor-chamber is located over the second integrated circuit devices. A heat-transfer member thermally couples the first heat spreader and the second heat spreader on both sides of the substrate.

In accordance with some embodiments, a semiconductor package is provided. The semiconductor package includes a substrate having a first surface and a second surface, first package components mounted on the first surface, and second package components mounted on the second surface. A first heat spreader in the form of a vapor-chamber (VC) is located over the first package components. A second heat spreader in the form of a vapor-chamber is located over the second package components. The second heat spreader includes a main body and a heat-transfer channel extended continuously from the main body to thermally contact the first heat spreader.

In accordance with some embodiments, a method of dissipating heat from a semiconductor package is provided. The method includes providing a package structure including a substrate, first integrated circuit devices mounted on the upper surface of the substrate, and second integrated circuit devices mounted on the lower surface of the substrate. The method includes disposing a first heat spreader in the form of a vapor-chamber (VC) to be thermally coupled to the first integrated circuit devices. The method includes disposing a second heat spreader in the form of a vapor-chamber to be thermally coupled to the second integrated circuit devices. The method includes thermally coupling the first heat spreader and the second heat spreader using one or more heat-transfer channels so that heat energy can be transferred from the second heat spreader to the first heat spreader The method also includes dissipating heat to an external environment through the first heat spreader.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate having an upper surface and a lower surface;
a plurality of first integrated circuit devices mounted on the upper surface;
a plurality of second integrated circuit devices mounted on the lower surface;
a first vapor-chamber (VC) heat spreader located over the plurality of first integrated circuit devices;
a second VC heat spreader located over the plurality of second integrated circuit devices; and
a heat-transfer member thermally coupling the first VC heat spreader and the second VC heat spreader.

2. The semiconductor package as claimed in claim 1, wherein each of the first VC heat spreader and the second VC heat spreader has a substantially flat plate structure and includes a vapor chamber containing a two-phase vaporizable liquid sealed therein, and
wherein the heat-transfer member is a VC heat-transfer channel and has the same structure as the first VC heat spreader and the VC second heat spreader.

3. The semiconductor package as claimed in claim 2, wherein the heat-transfer member is continuously extended from one VC heat spreader of the first VC heat spreader and the second VC heat spreader, and the heat-transfer member and the VC heat spreader share a single vapor chamber, and wherein a distal end of the heat-transfer member is in thermal contact with the other of the first VC heat spreader and the second VC heat spreader via a thermal interface material.

4. The semiconductor package as claimed in claim 2, wherein the first VC heat spreader, the second VC heat spreader, and the heat-transfer member are integrally formed and share a single continuous vapor chamber.

5. The semiconductor package as claimed in claim 2, wherein the heat-transfer member is C-shaped or vertical linear.

6. The semiconductor package as claimed in claim 1, further comprising:
a plurality of screws passing through the first VC heat spreader and the second VC heat spreader.

7. The semiconductor package as claimed in claim 1, further comprising:
a heat sink attached to the first VC heat spreader.

8. The semiconductor package as claimed in claim 7, wherein the first VC heat spreader is in thermal contact with the first integrated circuit devices on a first side of the first VC heat spreader through a thermal interface material, and the heat sink is attached to a second side of the first VC heat spreader opposite the first side.

9. The semiconductor package as claimed in claim 7, further comprising:
a third VC heat spreader located over and in thermal contact with the first integrated circuit devices through a thermal interface material,
wherein the first VC heat spreader is disposed on a side of the third VC heat spreader opposite the first integrated circuit devices, and the heat sink is located between and attached to the first VC heat spreader and the third VC heat spreader, and wherein the third VC heat spreader is not thermally coupled to the second VC heat spreader.

10. The semiconductor package as claimed in claim 9, further comprising:
a plurality of screws passing through the third VC heat spreader and the second VC heat spreader.

11. The semiconductor package as claimed in claim 1, further comprising:
a heat sink attached to the first integrated circuit devices through a thermal interface material,
wherein the first VC heat spreader is located over and in thermal contact with heat sink, and the heat sink is located between the first VC heat spreader and the first integrated circuit devices.

12. The semiconductor package as claimed in claim 1, wherein each of the first VC heat spreader and the VC second heat spreader has a substantially flat plate structure and includes a vapor chamber containing a two-phase vaporizable liquid sealed therein, and
wherein the heat-transfer member is a heat pipe and is connected to each of the first VC heat spreader and the second VC heat spreader through a thermal interface material or through soldering.

13. A semiconductor package, comprising:
a substrate having a first surface and a second surface;
a plurality of first package components mounted on the first surface;
a plurality of second package components mounted on the second surface;
a first vapor-chamber (VC) heat spreader located over the plurality of first package components; and
a second VC heat spreader located over the plurality of second package components, the second VC heat spreader comprising:
a main body; and
a heat-transfer channel extended continuously from the main body to thermally contact the first VC heat spreader.

14. The semiconductor package as claimed in claim 13, wherein no bonding interface is formed between the main body and the heat-transfer channel of the second VC heat spreader.

15. The semiconductor package as claimed in claim 13, wherein the first surface is an upper surface and the second surface is a lower surface of the substrate.

16. The semiconductor package as claimed in claim 15, further comprising:
a heat sink comprising fin structures attached to the first VC heat spreader.

17. The semiconductor package as claimed in claim 16, further comprising:
a third VC heat spreader in thermal contact with the first package components, wherein the heat sink is located between the first VC heat spreader and the third VC heat spreader and in thermal contact with both the first VC heat spreader and the third VC heat spreader.

18. The semiconductor package as claimed in claim 13, further comprising:
a system board; and
a plurality of screws passing through the first VC heat spreader, the second VC heat spreader, and the system board.

19. A method of dissipating heat from a semiconductor package, comprising:
providing a package structure comprising a substrate, a plurality of first integrated circuit devices mounted on an upper surface of the substrate, and a plurality of second integrated circuit devices mounted on a lower surface of the substrate;
disposing a first vapor-chamber (VC) heat spreader to be thermally coupled to the first integrated circuit devices;
disposing a second VC heat spreader to be thermally coupled to the second integrated circuit devices; and
thermally coupling the first VC heat spreader and the second VC heat spreader using one or more heat-transfer channels so that heat energy can be transferred from the second VC heat spreader to the first VC heat spreader.

20. The method as claimed in claim 19, wherein heat generated by the first integrated circuit devices during operation is distributed on the first VC heat spreader in a two-dimensional manner, and heat generated by the second integrated circuit devices during operation is distributed on the second VC heat spreader in a two-dimensional manner.
